(19) United States
(12) Patent Application Publication
(10) Pub. No.: US 2006/0214198 A1
(43) Pub. Date: Sep. 28, 2006

(54) Semiconductor device and manufacturing method thereof

(75) Inventors: Takeo Matsuki, Tsukuba-Shi (JP); Kazuyoshi Torii, Tokyo (JP)

Correspondence Address: YOUNG & THOMPSON, 745 SOUTH 23RD STREET, 2ND FLOOR, ARLINGTON, VA, 22202, US

(73) Assignees: NEC ELECTRONICS CORPORATION, KANAGAWA (JP); RENESAS TECHNOLOGY CORP., TOKYO (JP)

(21) Appl. No.: 11/385,885

(22) Filed: Mar. 22, 2006

(30) Foreign Application Priority Data
Mar. 23, 2005 (JP) 2005-084603

(51) Int. Cl. H01L 29/76

(52) U.S. Cl. 257/288

(57) ABSTRACT

An object of this invention is to prevent the NBTI degradation which may occur following the recent progress in miniaturization of the semiconductor device. By using a silicon nitride film, in which a concentration of Si—H bonds is not greater than 1×10²¹ cm⁻³, at least for a liner film or a second sidewall insulating film, the NBTI lifetime of the p-type MOS FET can be improved to be 1×10⁹ seconds, which secures sufficient lifetime for the semiconductor integrated circuit device.

### BACKGROUND OF THE INVENTION

1. Field of the Invention

The present invention relates to a semiconductor device and a manufacturing method thereof and more particularly to an improvement of a p-channel MOS FET (Metal Oxide Semiconductor Field Effect Transistor) comprised in a semiconductor device in reliability.

2. Description of the Related Art

In the semiconductor integrated circuit device, to improve its characteristics and increase its production yield, the miniaturization of the interconnection has been in progress. Along with the miniaturization of the interconnection, however, the areas for the gate, source and drain electrodes are also reduced. The gate, source and drain electrodes are connected through the contact holes with the interconnection formed on the interlayer insulating film, and the contact holes are formed by making firstly openings in the photoresist by means of photolithography and then applying anisotropic dry etching thereto through these openings.

Although the alignment of the mask that is to be used for the exposure with the electrode formed on the layer underlying the interlayer insulating film is made when these openings are formed in the photoresist by photolithography, an alignment shift somewhat tends to occur. With the miniaturization of the interconnection, such an alignment shift is liable to cause various problems. For instance, in forming a contact hole for connecting the drain electrode with the interconnection, there are occasions that it comes into contact with the neighbouring gate electrode, which cause a short circuit between the drain and the gate.

To solve these problems, the MOS FET used currently in the semiconductor integrated circuit device has such a structure as shown in FIG. 8(c).

For the transistor shown in FIG. 8(c), the mainstream structure comprises a layer called a liner layer 110 to serve, having a good etching selection ratio to the interlayer insulating film, as an etching stopper, which is formed after the formation of the transistor but before the formation of the interlayer insulating film.

Since a silicon oxide film is widely used as the interlayer insulating film, a silicon nitride film capable to provide a good etching selection ratio to the silicon oxide film is utilized as the liner layer.

Conventionally, the silicon nitride film is formed by the low pressure, atmospheric or plasma CVD (Chemical Vapor Deposition) method. As the miniaturization of the interconnection leads to the reduction of the areas for the gate, source and drain electrodes and, therefore, the increase in electrical resistance of the. electrodes, silicide is used to lower the electrical resistance.

When the silicidation of the gate electrode and drain/source regions is conducted, the Self-Aligned Silicidation (SALICIDE; referred to as “salicide”, hereinafter) for which the alignment using the mask is unnecessary is often employed.

When the salicide is used, the sidewall insulating film is formed of the sidewall of the gate electrode to prevent the short-circuit between the gate electrode and the source-drain electrodes. For the sidewall insulating film, a silicon oxide film can be utilized, but following the miniaturization of the designed dimensions of the device, silicon nitride film capable to provide a good etching selection ratio to the silicon oxide film is preferably used so as to secure sufficient margins in the step of forming a contact hole wherein etching is applied to the insulating film (referred to as a sidewall silicon nitride film hereinafter).

Examples of silicide include TiSi₂, CoSi₂, NiSi and such, but as the gate electrode becomes thinner along with the miniaturization of the interconnection, TiSi₂ and CoSi₂ may have a problem of having a high resistance due to agglomeration. To overcome this, the application of NiSi has been favorably investigated.

However, when the salicide of NiSi is applied, the heat of 500° C. or higher, in some cases, brings about the agglomeration/phase transition of silicide, and disadvantageously increases the sheet resistance. Therefore, in applying the salicide of NiSi, the liner layer of a silicon nitride film must be grown at deposition a temperature not higher than 500° C.

Consequently, the thermal CVD methods with high deposition temperatures (substrate temperatures) such as the low pressure CVD or atmospheric pressure CVD method cannot be employed so that the silicon nitride film is grown by the plasma CVD method in which the deposition can be made at low temperatures. Nevertheless, when the silicon nitride film is formed by the plasma CVD method, the gate occasionally receives the plasma damage.

To solve the above problems, there is disclosed in Japanese Patent Application Laid-open No. 217193/2002 an example in which a silicon nitride film is formed by the Catalytic-CVD (referred to as the Cat-CVD, hereinafter) method. Referring to the drawings, the structure of a p-type MOS FET fabricated using the salicide on the basis of the techniques disclosed in Japanese Patent Application Laid-open No. 217193/2002 and such (e.g. K. Ichinose et al., 2001 Symposium on VLSI Technology Digest of Technical Papers. p. 103-104, (2001)) and its manufacturing method are described below.

On a p-type silicon substrate 100, an element isolation region 101 is formed and then n-type dopants are by well-known ion implantation method implanted into a region surrounded with the element isolation region 101 to form a n-type well 102, which is a n-type dopant region (FIG. 6(a)). After that, an insulating film that is to serve as a gate insulating film 103 is formed on the substrate.

For the gate insulating film 103, the silicon oxide film has been in wide use, but recently there are occasions the silicon oxynitride film is utilized with the object of preventing boron which is implanted into the gate polysilicon electrode from diffusing into the channel (boron penetration). In the case of the oxide film, the film is normally formed by the thermal oxidation method, while with the silicon oxynitride film there is widely used the method in which the oxide film is first formed by the thermal oxidation method and thereafter, being subjected to the annealing in the nitriding atmosphere, the film is turned into the silicon oxynitride film.

Following that, a polycrystalline silicon film is formed and then applying the known method of photolithography and dry etching thereto, a gate electrode 104 is formed (FIG. 6(b)).

Subsequently, after a silicon oxide film that is to serve as a first sidewall insulating film 105 is formed so as to cover a lateral face of the gate electrode, implantation of boron or indium ions are carried out to form source/drain extension regions 106 (FIG. 6(c)).

Next, a silicon nitride film is grown by the thermal CVD method and then by means of dry etching a second sidewall insulating film 107 is formed in such a way that the first and the second insulating films may remain only in the sidewall section of the gate electrode 104. After that, conducting implantation of boron or boron fluoride ions and annealing, source/drain regions are formed (FIG. 7(a)).

Subsequently, refractory metal silicides 109 that are to function as gate/source and drain electrodes (FIG. 7(b)) by salicide in which a refractory metal layer is formed on the surface of the substrate and applying a heat treatment thereto, refractory metal silicides 109 are formed on the faces where the silicon film is exposed and thus after the unreacted refractory metal is removed, another heat treatment is applied to decrease their resistances. As the refractory metal, titanium and cobalt are preferably used. In an article by K. Ichinose et al. in 2001 Symposium on VLSI Technology Digest of Technical Papers p. 103-104 (2001), using cobalt, cobalt silicide films are formed on the surfaces of the gate electrode and source/drain regions.

After that, a first interlayer insulating film (a liner film) 110 that is to function as a stopper film is formed of a silicon nitride film (FIG. 7(c)) and thereon a second interlayer insulating film 111 is formed of an oxide film (FIG. 8(a)).

After that, with a photoresist film (not shown in the drawings) being applied onto the interlayer insulating film, by means of known photolithography, openings to form contact holes are first formed in the photoresist. and then, through those openings, known dry etching method is performed to make contact holes. Subsequently, these contact holes are filled up with metal, and thereby contact plugs are formed (FIG. 8(b)).

In many cases, the contact plugs are formed of metal such as tungsten 113 with which the contact holes are filled up after their inner surfaces are first coated with titanium nitride films 112.

After that, the interconnection 114 is formed over contact plugs (FIG. 8(c)).

In Japanese Patent Application Laid-open No. 217193/2002, the deposition of the first interlayer insulating film 110 as well as the second sidewall insulating film 107 to be formed on the sidewall of the polysilicon that is to serve as the gate electrode are carried out by the Cat-CVD method.

Next, the Cat-CVD method is described.

As shown in FIG. 10, the Cat-CVD method is the deposition method wherein the source gas is fed into the reaction furnace through its supply inlet for the source gas 801, and a film is formed on a substrate 803 by catalytic reaction of the source gas on a heated and energized filament 802, and this method characteristically allows the film deposition to be made at low substrate temperatures.

For the deposition of a silicon nitride film, monosilane (SiH₄), disilane (Si₂H₆) or such may be used as the source gas and nitrogen gas (N₂) or ammonia (NH₃), as the nitrogen source gas. As for the catalyst, for instance, tungsten (W) can be used.

FIG. 11 is a schematic diagram illustrating the state in which monosilane and ammonia used as the source gas are decomposed, while passing through the tungsten filament section which is heated with the electric current flow, with the tungsten filament section having the catalytic power, and thereby a silicon nitride film (SiN film) is grown on the substrate.

In Japanese Patent Application Laid-open No. 217193/2002, a silicon nitride film was grown under the conditions that the flow rate of SiH₄ was 1 scorn (standard cubic centimeters minute); the flow rate of NH₃, 40 scom; the substrate temperature, 300° C. and the catalyst temperature, 1400° C.

This result shows that the substrate temperature can be lowered down to 300° C., which makes it possible to improve the film characteristics of the silicon nitride film, lower the deposition temperature, become free from the plasma damage and avoid the problems of changes in the threshold voltage which are brought about by the dopants of boron in the polysilicon constituting the gate electrode in the p-type MOS transistor penetrate through the gate insulating film and the problems of increases in contact resistance caused by the silicide agglomeration.

In Japanese Patent Application Laid-open No. 217193/2002 it is described that through the use of the Cat-CVD method for forming the silicon nitride film, the substrate temperature during the deposition could be lowered and, in consequence, the increase in resistance, which may be brought about by the silicide agglomeration, and the boron penetration which may be caused by the heat during the deposition of the silicon nitride film, with boron in polysilicon used as the gate electrode passing through the gate insulating film to change its substrate surface density and raise the threshold voltage, was well suppressed with effect.

Meanwhile, as the miniaturization of the semiconductor integrated circuit device advances, the gate insulating film has become considerably thin. As a result, the electric field applied to the gate insulating film becomes heightened. In particular, when a negative bias (a negative gate bias is a positive bias for the p-MOS FET) is applied to the p-MOS FET at high temperature, there occurs the phenomenon called the NBTI (Negative Bias Temperature Instability) (D. K. Shroder and J. A. Babcock J. App. Phys. (2003) Vol. 94, No. 1, p. 1-18). It is generally known that the NBTI lifetime limits the device lifetime.

FIG. 9 is a schematic view in explaining the cause of the NBTI. The second sidewall insulating film 107 formed of silicon nitride on the gate sidewall and the liner film 110 contain a great amount of Si—H bonds and H (Hydrogen) atoms dissociated from these Si—H bonds migrate toward the gate insulating film. In the gate insulating film of SiO₂ or at the interfaces between the nitride films and the substrate, Si dangling bonds are present, forming the carrier trap states. For their reduction, annealing in the hydrogen atmosphere at a temperature of 400° C. to 450° C. or so is often performed to terminate the dangling bond with hydrogen. Once the free hydrogen released from the Si—H bond reaches the gate insulating film, however, it reacts with hydrogen of hydrogen terminated Si dangling bond and removes hydrogen therefrom, to leave behind another Si dangling bond. In short, this is thought to result in an increase in interface state density.

With further advance in the miniaturization of the interconnection, the gate insulating film is apt to become still thinner so that further improvement on NBTI performance is much waited for.

Although the precise cause of the NBTI degradation has not been elucidated yet, it is empirically known that when the concentration of the Si—H bonds in the liner film is high as described above, the NBTI is heightened (K. Ichinose et al. 2001 Symposium on VLSI Technology Digest of Technical Papers (2001), p. 103-104).

Moreover, in Japanese Patent Application Laid-pen No. 343962/2002, it is described that the reduction of the hydrogen content in the silicon nitride film adjacent to the gate electrode can improve the NBTI lifetime.

### SUMMARY OF THE INVENTION

The present invention relates to a semiconductor integrated circuit device comprising a MOS (Metal Oxide Semiconductor) field effect transistor disposed on a semiconductor substrate; wherein a concentration of Si—H bonds comprised at least in one of a plurality of insulating films which is laid on a gate electrode of the Metal Oxide Semiconductor field effect transistor either directly touching or sandwiching a thin film therebetween is not greater than 1×10²¹ cm⁻³. Further, the present invention relates to a semiconductor integrated circuit device, wherein either the insulating film laid thereon sandwiching a thin film therebetween is a silicon nitride film formed on a lateral face of the gate electrode or the insulating film directly touching the gate electrode is a silicon nitride film covering the gate electrode, source and drain, and a concentration of Si—H bonds comprised at least in one of the two silicon nitride films is not greater than 1×10²¹ cm⁻³.

The present invention relates to a method of manufacturing a semiconductor integrated circuit device wherein a field effect transistor is formed in a region separated by an element isolation region that is formed on a semiconductor substrate; which at least comprises the steps of forming a gate insulating film in a region separated by the element isolation region; forming a gate electrode; forming a sidewall silicon nitride film on a lateral face of the gate electrode; forming source/drain regions; and thereafter forming a silicon nitride film; wherein the sidewall silicon nitride film and the silicon nitride film are formed in such a way that a concentration of Si—H bonds in at least one of the silicon nitride films is not greater than 1×10²¹ cm⁻³.

In the present invention, it is preferable that after the step of forming either the sidewall silicon nitride film or the silicon nitride film lying directly on the gate electrode and covering the source/drain, the step of conducting annealing at an annealing temperature set equal to or higher than the substrate temperature of the film is comprised.

Further, in the present invention, it is preferable that the step of forming the gate electrode comprises the step of forming at least a metal film; forming a silicon nitride film; and patterning the silicon nitride film into the shape of a prescribed pattern and then forming a gate electrode by means of etching with the pattern being used as a mask; and either the silicon nitride film is formed, by the chemical vapor deposition method on the semiconductor substrate, from constitutive particles of the film which are produced in the presence of a catalyst through decomposition of a source gas; or the nitride film is formed by the thermal CVD method and the step of conducting annealing at an annealing temperature set equal to or higher than the substrate temperature of the film is further comprised.

By using a silicon nitride film, in which a concentration of Si—H bonds is not greater than 1×10²¹ cm⁻³, at least for a liner film or a second sidewall insulating film, the NBTI lifetime of the p-type MOS FET can be improved to be not less than ten years, which secures sufficient lifetime for the semiconductor integrated circuit device.

### BRIEF DESCRIPTION OF THE DRAWING

FIG. 1 is a graph showing the dependences of the concentrations of Si—H bonds and N—H bonds on the deposition conditions of the Cat-CVD.

FIG. 2 is a graph showing the relationship between the concentration of Si—H bonds and the NBTI lifetime for the p-type MOS FET.

FIG. 3 is a graphic representation depicting the NBTI lifetime for various structures.

FIG. 4 is a graphic representation showing annealing temperature dependences of changes in concentration in the film for Si—H bonds and N—H bonds.

FIG. 5 is a graphic representation depicting the NBTI lifetime for various annealing temperatures.

FIG. 6 is a series of schematic cross-sectional views illustrating the steps of a manufacturing method of a MOS FET.

FIG. 7 is a series of schematic cross-sectional views illustrating further steps of a manufacturing method of a MOS FET.

FIG. 8 is a series of schematic cross-sectional views illustrating further steps of a manufacturing method of a MOS FET.

FIG. 9 is a schematic view in explaining the NBTI lifetime.

FIG. 10 is a schematic view in explaining the Cat-CVD.

FIG. 11 is a schematic view in explaining the state in which a silicon nitride film is grown by the Cat-CVD method.

FIG. 12 is a set of schematic views each showing a modified example of a MOS FET according to the present Invention.

### DETAILED DESCRIPTION OF THE INVENTION AND PREFERRED EMBODIMENTS

The structure and manufacturing method thereof are basically the same as described in Prior Art. The only points the present embodiments differ from the conventional technique are described below. It is to be understood that although the referential numerals corresponding to those in Prior Art are given in the following drawings, this is for purpose of illustration only and is not intended as a definition of the limits of the invention.

In the present embodiments, as a gate insulating film, a silicon oxynitride film was formed to have a film thickness of 1.5 nm in terms of the silicon oxide film thickness.

For a polycrystalline silicon film that was to serve as a gate electrode, a polycrystalline silicon film was formed to a thickness of 130 nm by a known CVD method.

For a first and a second sidewall insulating film, a silicon oxide film with a thickness of 10 nm and a silicon nitride film with a thickness of 80 nm were formed, respectively.

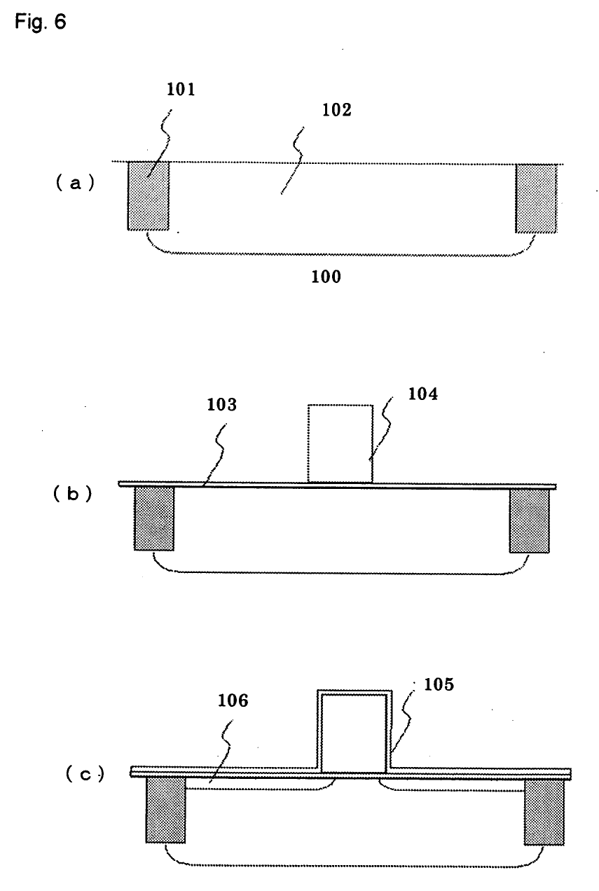

After forming the first sidewall insulating film, doping of boron was performed by means of ion implantation to form source/drain extension regions (FIG. 6(c)). Hereat, to form a shallow PN junction, the ion implantation energy was set to be 0.4 keV. In addition, around the source/drain extension regions, it can be selectively formed a region called a Halo region where the substrate dopant concentration is increased by injecting dopants (As, P or such) which can provide a region with the same conductive type as the substrate semiconductor from the oblique direction with respect to the substrate. In this way, so-called short-channel effects can be suppressed, to the advantage of the device miniaturization.

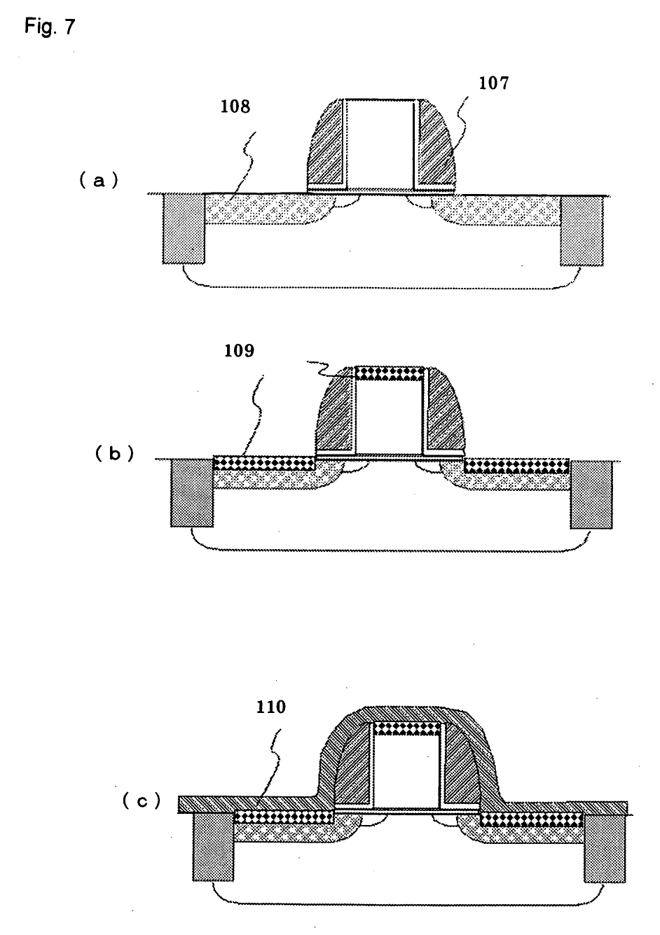

After forming a second sidewall (FIG. 7(a)), boron fluoride for formation of source/drain regions was implanted by means of the ion implantation and then activated by conducting a heat treatment at a high temperature in a short period of time.

Subsequently, by growing refractory metal and then annealing it, a silicide film was selectively formed on the surfaces of the gate electrode and the source/drain regions and thereafter unreacted metal was selectively removed therefrom (FIG. 7(b)).

For silicide, TiSi₂, CoSi₂ and NiSi can be utilized. However, in case of NiSi, because its heat resistance is lower than those of TiSi₂ and CoSi₂, as described above, the process temperature after the step of forming the silicide must be controlled to be 500° C. or lower.

Further, in the salicide process, consecutively after forming a film of transition metal but before carrying out a heat treatment for silicidation, a titanium nitride film can be grown to an appropriate thickness. Such titanium nitride is selectively removed after the heat treatment.

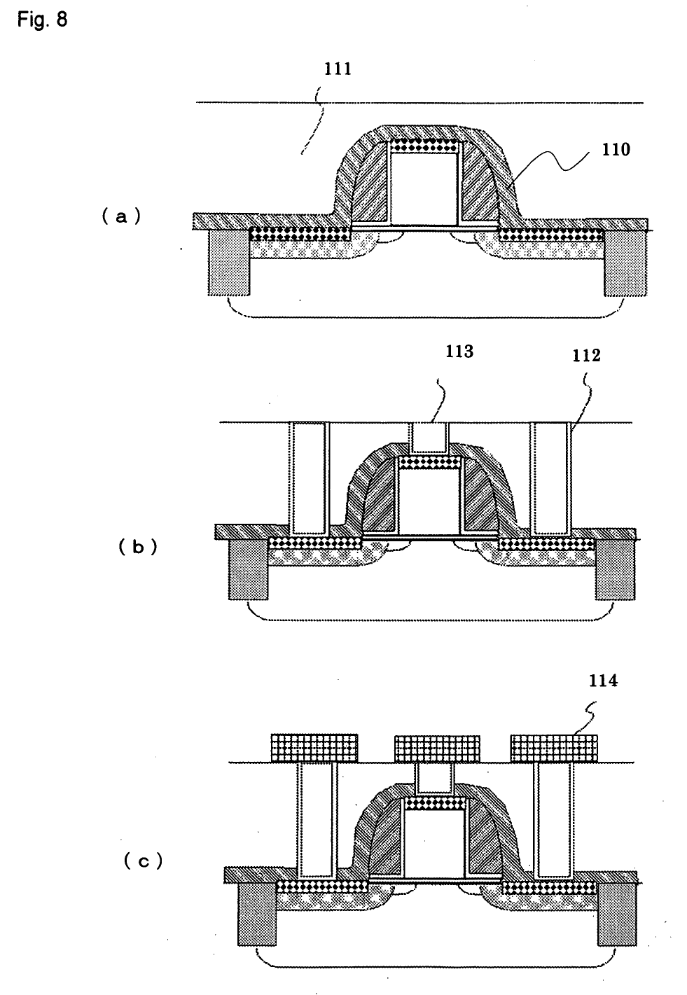

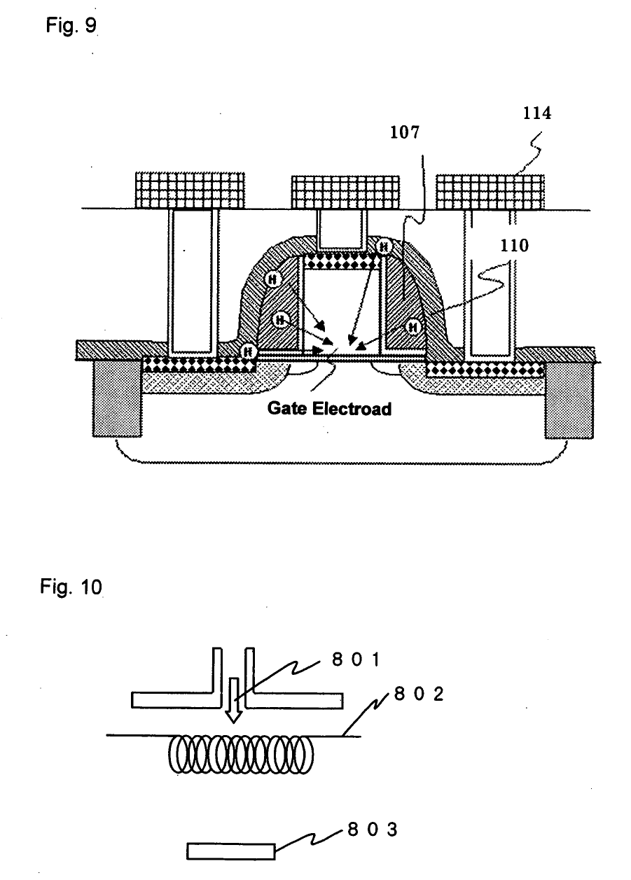

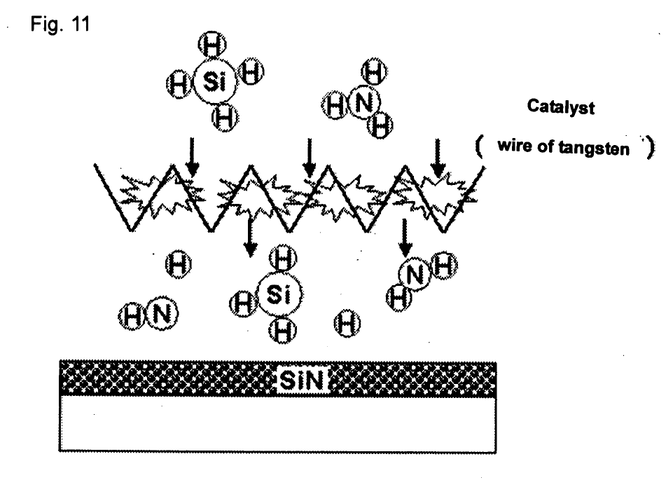

Next, as a first interlayer insulating film (a liner film or an etching stopper film) a silicon nitride film with a thickness of 40 nm was formed (FIG. 7((c) and thereafter as a second interlayer insulating film a silicon oxide film with a thickness of 500 nm was formed (FIG. 8(a)).

In respect of contact holes, after titanium nitride films with a thickness of 10 nm were formed inside the contact holes, tungsten was grown by a known CVD method so as to fill up the contact holes and then an aluminum interconnection was formed thereon (FIG. 8(c)).

While for both of the second sidewall insulating film and the first interlayer insulating film, silicon nitride films are used, silicon nitride films grown by the Cat-CVD method or the thermal CVD method were in the present examples employed.

For the formation f the second sidewall insulating film, the thermal CVD method, with silane and disilane being used as the Si source, can be used and, in that case, the deposition temperature was set at 600° C. or so. On the other hand, when Hexa-chloride-disilane (HCD) was used as the silicon source gas to form the second sidewall insulating film, the decomposition of the source and the deposition of the film can be carried out at a temperature not higher than 500° C.

In the step of forming the second sidewall insulating film, dopants which have been implanted beforehand into the gate electrode formed of polysilicon can be prevented from diffusing into the substrate silicon. In other words, the temperature regulation of this sort makes it possible to prevent dopants, which have been implanted beforehand into the gate electrode, from passing through the gate insulating film comprising boron and such, and diffusing into the substrate silicon, and thereby suppress the threshold voltage shift and the increase in interface state density.

Further, in the step of forming the first interlayer insulating film, the heat resistance of the material laid thereunder must be taken into account. For instance, when TiSi₂ or CoSi₂ is used for the salicide, a silicon nitride film is preferably grown by the thermal CVD method using silane or disilane as the Si source and with substrate temperature being set at or below 700° C. during the deposition. On the other hand, if NiSi is used for the salicide, a silicon nitride film is preferably grown by the thermal CVD method using HCD as the Si source or the Cat-CVD method with a substrate temperature of 450° C. or lower.

For the first interlayer insulating film, it is also possible to use a silicon nitride film being applied thereto by the plasma CVD method with a substrate temperature set at or below as long as the step coverage is sufficiently provided.

While the foregoing structure and manufacturing method are given, to illustrate the present invention, as typical structure and manufacturing method, it will be obvious to those skilled in the art that various changes and modifications may be made without departing from the spirit and the scope of the present invention.

### FIRST EXAMPLE

In the present example, the second sidewall insulating films were grown by the thermal CVD method and the liner film, by the Cat-CVD method. In the present Example, NiSi was used for salicide.

Firstly, according to the method described in the previous section of the preferred embodiments, the steps up to the step of forming a second sidewall insulating film were carried out.

The second sidewall insulating film was formed by growing a film to a thickness of 80 nm by the thermal CVD method using the HCD as the Si source at a substrate temperature of 450° C. as described above, and then applying anisotropic dry etching thereto.

After Ni was formed to a thickness of 8 nm by the sputtering method, NiSi was formed in the manner of self-alignment on the surfaces of the gate electrode and source/drain regions by annealing at 450° C. for 30 seconds. Next, a liner film was formed to a thickness of 40 nm by the Cat-CVD method. In the Cat-CVD method, the deposition conditions of the Cat-CVD were as follows. The pressure in the deposition furnace was once lowered to 1×10⁻⁶ Pa or so by exhausting the air therefrom, before the catalyst (tungsten filament) was heated up by making the current flow therethrough. The deposition were then carried out, supplying as the source gas monosilane and ammonia at flow rates of 12 sccm and 300 sccm, respectively, and setting the pressure in the deposition surface was set at 5 Pa, while the substrate temperature and the tungsten filament temperature (the catalyst temperature) were set at a various temperatures in regions of 100° C. to 200° C. and 1700° C. to 2100° C., respectively.

In the present examples, the relationships between the concentrations of Si—H bonds and N—H bonds contained in the liner film as well as the relationship between the concentration Si—H bonds and the NBTI lifetime of p-type MOS FET were examined.

The measurements of the amounts of the Si—H bonds and N—H bonds were made for silicon nitride films which were separately grown on Si substrates for that purpose under the same fabrication conditions as devices for the measurements of the NBTI lifetime. The Si—H bond concentration and the N—H concentration in the silicon nitride film were calculated from the area of the peak arising from the Si—H in the infrared spectroscopy spectrum obtained by Fourier Transform Infrared Spectroscopy (FT-IR). Infrared spectroscopy is the method to analyze the film quality by making use of the fact that chemical bonds (Si—H, Si—O, Si—N, Si—F, Si—OH, N—H and such) which fundamentally characterize the film composition have strong absorption peaks at specific wavelengths of the infrared light, respectively, and the Si substrate is substantially transparent to the infrared light. When the sample molecule is irradiated with the infrared light comprising a frequency which corresponds to an eigenfrequency of the molecule, the molecule absorbs the radiation, which induces the transition from the ground level to an excited level within a set of its allowed vibrational energy levels. Accordingly, when the absorption spectrum with the infrared light is measured, the amount of a specific bond may be obtained from the area of the peak at its characteristic wavelengths in the absorption spectrum.

The measurements of the amount of bonds in the following Examples were all made by the FT-IR method described above.

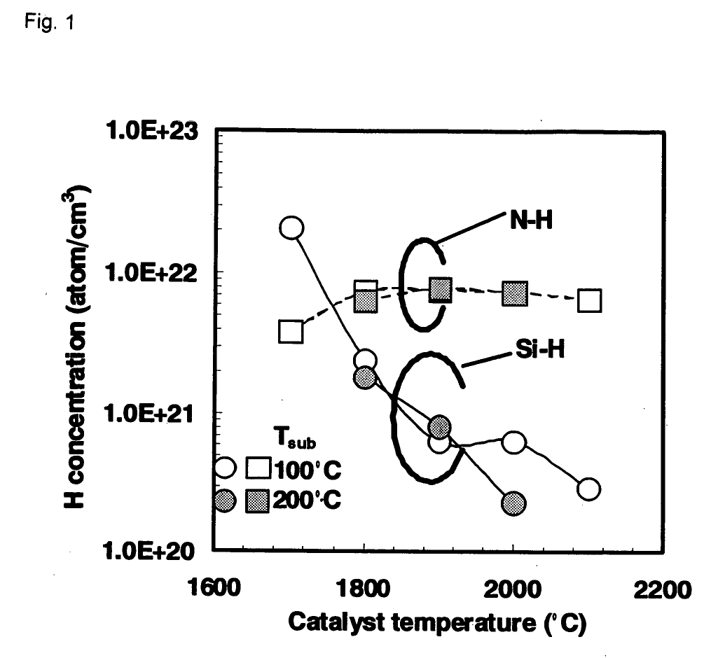

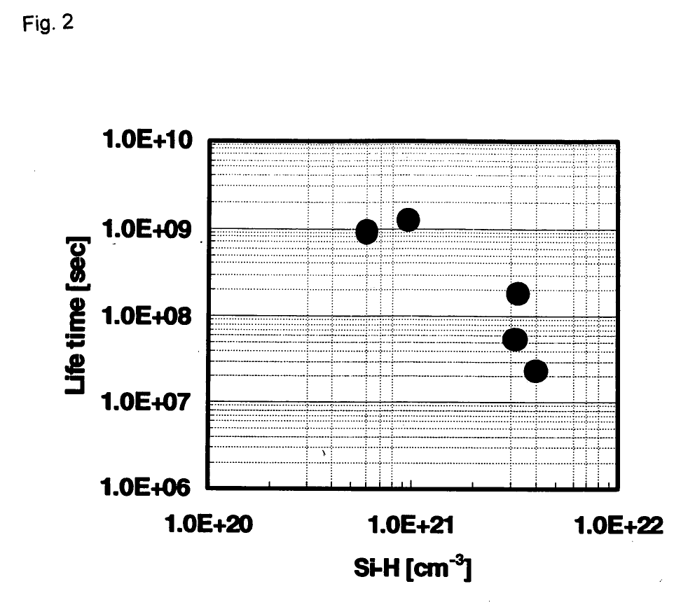

FIG. 1 is a graph showing the dependences of the concentrations of the Si—H bonds and N—H bonds. FIG. 2 is a graph depicting the relationships between the concentration of the Si—H bonds and the NBTI lifetime for the p-type MOS FET with a gate voltage of −1.1 V.

The threshold voltage shift of 30 mV at 125° C. was made to be the criterion by which the lifetime was measured.

Further, in the following Examples, all the measurements of the NBTI lifetime were made under the above conditions.

FIG. 1 shows that in this range of the substrate temperature, the amounts of neither Si—H bonds nor N—H bonds in the silicon nitride film are dependent on the substrate temperature, but both or them are dependent on the catalyst temperature.

FIG. 2 indicates that 10 years of the NBTI lifetime is secured under the conditions that the concentration of the Si—H bonds in the silicon nitride film is not higher than 1×10²¹ cm⁻³. According to FIG. 1, this condition is met when the catalyst temperature is 1900° C.

Although tungsten was used in the present example as the catalyst, obviously any of other refractory metals such as molybdenum or an alloy of a refractory metal and a noble metal such as the Pt group can be used.

### SECOND EXAMPLE

In the present example, a second sidewall insulating film and a first interlayer insulating film were grown by the Cat-CVD method. Conditions for the Cat-CVD were that the substrate temperature and the catalyst temperature were set at 200° C. and 1900° C., respectively, so that Si—H bonds may become 1×10²¹ cm⁻³ or lower. The film thickness was set to be 80 nm. For the salicide, NiSi was employed.

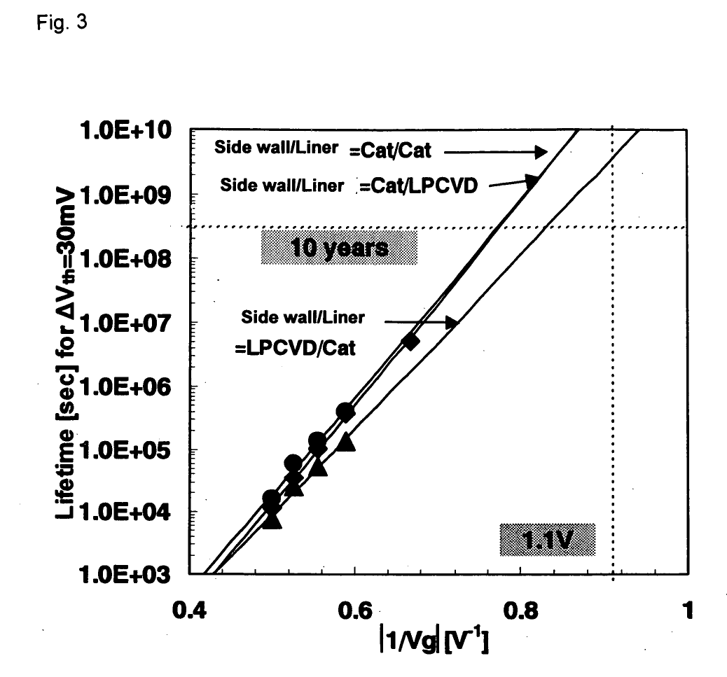

FIG. 3 presents the result of the NBTI lifetime evaluation. Compared with First Example in which the second sidewall film was formed by means of thermal CVD and the first interlayer insulating was grown by the Cat-CVD method, the deposition of the second sidewall insulating film by the CVD method enabled to certainly prolong the NBTI lifetime.

Further, in the case that the second sidewall insulating film was formed by the Cat-CVD method and the first interlayer insulating film of a silicon nitride film was grown to a thickness of 40 nm by the thermal CVD method, using HVD as the silicon source, the NBTI lifetime coincides with that of the example wherein the second sidewall insulating film and the first interlayer insulating film were both formed by the Cat-CVD method, as shown in FIG. 3.

This demonstrates that the use of a silicon nitride film with a fewer Si—H bonds for the second sidewall insulating film is more effective than the use of a silicon nitride film with a fewer Si—H bonds for the first interlayer insulating film.

### THIRD EXAMPLE

The present example differs from the foregoing embodiments of the present invention in an additional application of the annealing after the deposition of the first interlayer insulating film.

To explain the present example, the amounts of the Si—H bonds and N—H bonds remaining in the silicon nitride film after annealing at various temperatures were examined.

The silicon nitride film was grown directly on the silicon substrate by the Cat-CVD method.

The Cat-CVD was conducted under the conditions that the substrate temperature was 100° C. and the catalyst temperature of tungsten, 2000° C.

The conditions of the annealing after the deposition were as follows.

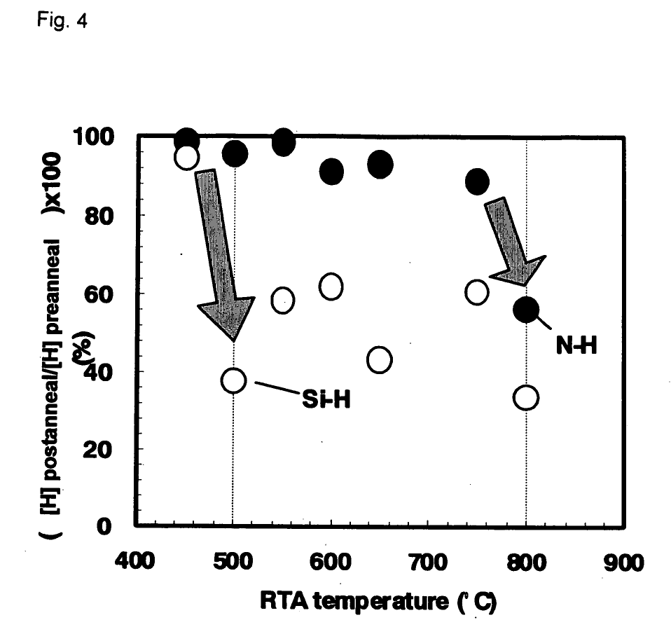

The annealing time was set to be 30 seconds and the annealing temperature, in a range between 400° C. and 800° C. The concentrations of Si—H bonds and N—H bonds were measured before and after annealing and the results are shown in FIG. 4, wherein for both bonds the ratios of after annealing value to the initial value are plotted against the annealing temperature. While the amount of Si—H bonds remained after annealing at 450° C. was still 90% of the pre-annealing amount, annealing at a temperature of 500° C. or higher reduced the remaining amount of bonds to 60% or less. As for the N—H bonds, the after annealing amount decreased to the level of 69% only after the annealing temperature is raised to 800° C.

Now, taking account of the above results, the present example in which CoSi₂ was used for salicide and after growing a silicon nitride film for the first interlayer insulating film, an annealing was conducted by the Cat-CVD is described below.

According to the method described in the section of the preferred embodiments, up to the step of forming a second sidewall insulating film, the steps were carried out. A second sidewall insulating film of a silicon nitride film was grown at a deposition temperature of 450° C. to a thickness of 80 nm by the thermal CVD method, using HCD as the silicon source.

Co was grown to a thickness of 9 nm and, consecutively, titanium nitride was grown to a thickness of 15 nm and then an annealing was conducted at 500° C. for 30 seconds. After the titanium nitride and unreacted Co were selectively removed, for the purpose of lowering the electrical resistance of CoSi₂, another annealing was carried out at 800° C. for 10 seconds.

Following that, a first interlayer insulating film of a silicon nitride film was grown to a thickness of 40 nm by the Cat-CVD method. The conditions used for the deposition were that the substrate temperature was 100° C. and the catalyst temperature, 1800° C.

This annealing was performed at 800° C. and an interconnection as formed by the method described in the previous section of preferred embodiments.

The NBTI lifetime was estimated to be not less than 10 years.

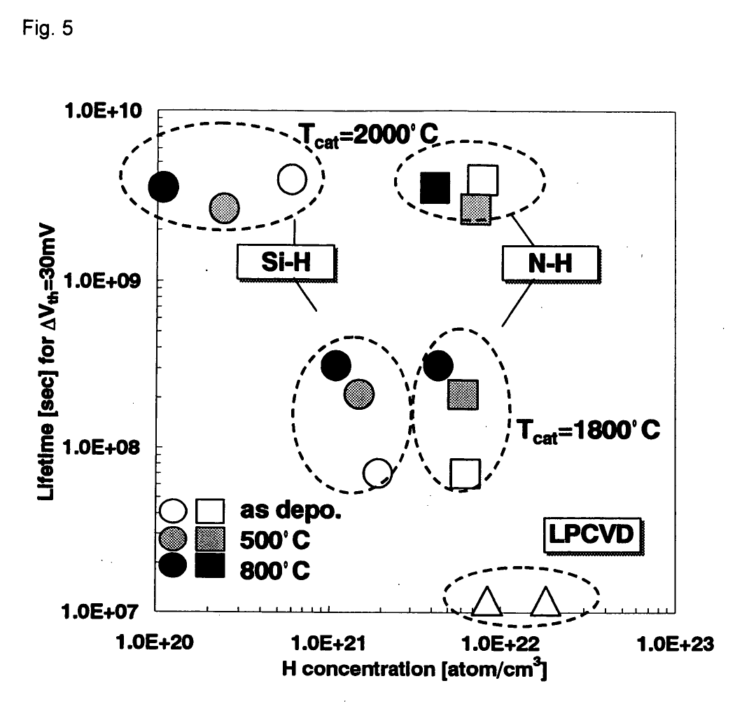

In addition, for the device for which the catalyst temperature was set at 2000° C. while growing a first interlayer insulating film of a silicon nitride film by the Cat-CVD as well as the device for which the annealing after the deposition was conducted at 500° C., the NBTI lifetimes were assessed and together with the results of the present example, those results are shown in FIG. 5.

When the annealing was conducted at 500° C. after the film depositions were made at catalyst temperatures of 1800° C. or 2000° C., the concentrations of Si—H bonds were in either case found to be 50% to 60% of the initial amount. This considered together with the result of FIG. 1, it is evident that the concentration of Si—H bonds in the silicon nitride film can be made 1×10²¹ cm⁻³ by growing the film at a temperature higher than 1800° C. and thereafter annealing at a temperature not lower than 500° C. Moreover, when the concentration of the Si—H bonds remained in the film is 1×10²¹ cm⁻³ or so, even if the concentration of N—H bonds remained as much as 1×10²² cm⁻³ or so, a lifetime of 10 years can be certainly secured.

Further, it was demonstrated that a lifetime of 10 years can be attained simply by setting the catalyst temperature higher than 1800° C. so as to make the concentration of remaining Si—H bonds 1×10²¹ cm⁻³ or so.

Further, when by using the plasma CVD method with a high hydrogen concentration a silicon nitride film was grown to have a concentration of Si—H bonds of 2×10²² cm⁻³ or higher and then subjected to an annealing in the inert gas atmosphere at 800° C. for 30 seconds, the measurement of the amount of the Si—H bonds after annealing revealed that the concentration of Si—H bond dropped to 1×10²¹ cm⁻³ or less.

This indicates that even if the silicon nitride film contains Si—H bonds with a concentration of not lower than 1×10²¹ cm⁻³, an application of annealing at a temperature that is not lower than the deposition temperature of the film can lower the concentration of Si—H bonds, and therefore can affect the NBTI lifetime advantageously. Regarding the annealing time, its length can be obviously determined depending the concentration of Si—H bonds immediately after the deposition.

The deposition temperature as used herein refers to the substrate temperature during the deposition of the silicon nitride film.

### FOURTH EXAMPLE

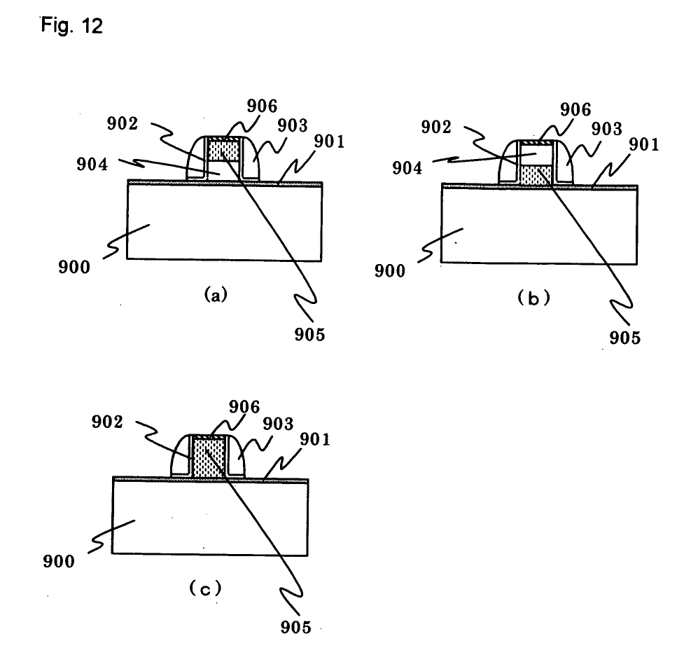

The present example is an example wherein the material and the structure of the gate electrode are changed from those described in the previous section of the preferred embodiments. Since further progress in miniaturization of the interconnection is expected to increase the electrical resistance of the afore-mentioned polysilicon gate electrode with the polysilicon/silicide structure, the polysilicon/metal structure (FIG. 12(a)) has been investigated. Moreover, when a positive bias is applied to the gate electrode of polysilicon, a depletion layer being formed within the gate electrode, its current driving capability is worsened so that, for the sake of improving this capability, the structure of the gate electrodes other than the polysilicon/silicide structure, namely, the metal/polysilicon structure (FIG. 12(b)) wherein the gate electrode being in contact with the gate insulating film is made of metal and a layer of polysilicon is laid thereon and the metal structure (FIG. 12(c)) have also become the subject of studies.

To form the gate electrode with the polysilicon/metal structure shown in FIG. 12(a), a gate insulating film 901 is formed on a semiconductor substrate 900, and on the gate insulating film 901, a polysilicon layer 904, a metal layer 905 and a layer of a silicon nitride film 906 are formed in this order, and besides on a lateral face of the gate electrode, a first sidewall insulating film 902 is formed of a silicon oxide film, and on the first sidewall insulating film, a second sidewall insulating film 903 is formed of a silicon nitride film. In the structure shown in FIG. 12(b), reversing the order of a polysilicon layer 904 and a metal layer 905, a metal layer 905 and a polysilicon layer 904 are formed on a gate insulating film in this order. The gate electrode with the metal structure shown in FIG. 12(c) differs from the gate electrode with the polysilicon/metal structure only in a point that, without a polysilicon layer, a metal layer 905 and a layer of a silicon nitride film 906 are formed in this order on an insulating film 901.

In the gate electrode with the structure comprising a metal layer and a polysilicon layer as shown in FIG. 12(a) and FIG. 12(b), the thicknesses of the polysilicon layer and the metal layer are preferably determined as the manufacturing steps require.

When metal is used for the gate electrode, the employment of the photoresist film as dry etching mask tends to cause problems. In this case, the silicon nitride film is utilized for the mask, but the silicon nitride film is liable to be left behind on the metal.

In depositing a silicon nitride film on metal, it is often difficult to set a temperature high for the deposition temperature, and therefore preferably the silicon nitride film that is to serve as a hard mask is either formed by the Cat-CVD method or formed by the thermal CVD method set at a low temperature and then subjected to an annealing conducted at a temperature of 400° C. to 450° C. so as to lower the Si—H concentration in the silicon nitride film.

It is apparent that the annealing can be carried out either after the silicon nitride film is formed or after the gate electrode is formed, according to the circumstances.

### FIFTH EXAMPLE

Recently, a considerable number of reports on techniques to apply the metal oxide having a dielectric constant higher than the silicon dioxide and silicon oxynitride to the gate insulating film (referred to as the high-dielectric-constant film (metal oxide material), hereinafter) have been made. Examples of such material include Al₂O₃, HfO₂, substances in which Al or Si is added into one of these above two, ZrO₂ and oxides of La and La type elements (lanthanoids). Further, high-dielectric-constant films which are formed by nitriding one of the above metal oxides either in the ammonia atmosphere or with the ammonia plasma are also known. The present invention can apply to the gate insulating film formed of such a high-dielectric-constant film with good effect. The explanation lies in the fact that the NBTI degradation is caused by generation of the Si dangling bonds at the interface of the substrate, and the NBTI degradation in this case can be well suppressed by the methods described above since the gate insulating film formed of a high-dielectric-constant film is, in the first place, utilized owing to its characteristics to allow structurally a silicon oxide film or a silicon nitride film to lie at its interface with the silicon substrate.

In the case that the afore-mentioned high-dielectric-constant film is used as the gate insulating film, a silicon oxide film is apt to be formed at the interface between the gate insulating film and the silicon substrate. In other words, the gate insulating film has the layered structure wherein a high-dielectric-constant film and a silicon oxide film are placed at the interface. In consequence, it is well known that the film structure may be controlled satisfactorily by forming first on the surface of the silicon substrate a silicon oxide film or a silicon oxynitride film to a thickness of 1 nm or less as an interface film, and then forming a high-dielectric-constant film, in the manufacturing process. The thickness of the interface film is preferably set to be not greater than 1 nm but, in practice, the dielectric constant of the overlying high-dielectric-constant film should be taken into consideration.

An example wherein HfSiON formed by mixing Si into HfO₂ and nitriding is utilized for the high-dielectric-constant film is described below. As for the method of manufacturing other parts constituting a field effect transistor, the foregoing methods may be employed appropriately, and, therefore, only the method of manufacturing a gate insulating film is herein described.

On a silicon substrate, a silicon oxide film with a thickness of 0.7 nm is formed by applying thermal oxidation to the silicon substrate surface. Next, by the CVD method, a HfSiO film is formed to a thickness of 2.3 nm. The composition ratio of Hf to Si is herein set 1:1. An annealing is successively applied thereto in the ammonia atmosphere, whereby a HfSiO film is changed to a HfSiON film.

In the steps after the deposition of the dielectric-constant film is completed, annealing may be advantageously conducted at a temperature higher than the deposition temperature to improve the film quality.

What is clamed is:

1. A semiconductor integrated circuit device comprising a Metal Oxide Semiconductor field effect transistor disposed on a semiconductor substrate; wherein
a concentration of Si—H bonds comprised at least in one of a plurality of insulating films which is laid on a gate electrode of said Metal Oxide Semiconductor field effect transistor either directly touching or sandwiching a thin film therebetween is not greater than 1×10²¹ cm⁻³.

2. A semiconductor integrated circuit device according to claim 1, wherein either said insulating film laid thereon sandwiching a thin film therebetween is a silicon nitride film formed on a lateral face of said gate electrode or said insulating film directly touching the gate electrode is a silicon nitride film covering said gate electrode, source and drain, and a concentration of Si—H bonds comprised at least in one of the two silicon nitride films is not greater than 1×10²¹ cm⁻³.

3. A method of manufacturing a semiconductor integrated circuit device wherein a Metal Oxide Semiconductor field effect transistor is formed in a region separated by an element isolation region that is formed on a semiconductor substrate; which at least comprising:
forming a gate insulating film in a region separated by said element isolation region;
forming a gate electrode;
forming a sidewall silicon nitride film on a lateral face of the gate electrode;
forming source/drain regions; and thereafter
forming a silicon nitride film; wherein
said sidewall silicon nitride film and said silicon nitride film are formed in such a way that a concentration of Si—H bonds in at least one of said silicon nitride films is not greater than 1×10²¹ cm⁻³.

4. A method of manufacturing a semiconductor integrated circuit device according to claim 3, wherein at least one of said sidewall silicon nitride film and said silicon nitride film covering the gate electrode, source and drain is formed, on said semiconductor substrate, from constitutive particles of the film which are produced in the presence of a catalyst through decomposition of a source gas.

5. A method of manufacturing a semiconductor integrated circuit device according to claim 4, wherein a temperature of said catalyst is exceed 1800° C.

6. A method of manufacturing a semiconductor integrated circuit device according to claim 4, wherein a temperature of said semiconductor substrate is not higher than 450° C.

7. A method of manufacturing a semiconductor integrated circuit device according to claim 3, which further comprises, after the step of forming either said sidewall silicon nitride film or said silicon nitride film covering said gate electrode, source and drain, the step of conducting annealing at an annealing temperature equal to or higher than the substrate temperature of the film.

8. A method of manufacturing a semiconductor integrated circuit device according to claim 7, wherein said annealing temperature is a range of 450° C. to 800° C.

9. A method of manufacturing a semiconductor integrated circuit device according to claim 3; wherein
the forming said gate electrode comprises:
forming at least a metal film;
forming a silicon nitride film; and
patterning said silicon nitride film into the shape of a prescribed pattern and then forming a gate electrode by means of etching with said pattern being used as a mask; wherein
said silicon nitride film is formed, by the chemical vapor deposition method, on said semiconductor substrate, from constitutive particles of the film which are produced in the presence of a catalyst through decomposition of a source gas.

10. A method of manufacturing a semiconductor integrated circuit device according to claim 3; wherein the forming said gate electrode comprises:
forming at least a metal film;
forming a silicon nitride film; and
patterning said silicon nitride film into the shape of a prescribed pattern and then forming a gate electrode by means of etching with said pattern being used as a mask; wherein
said nitride film is formed by the thermal CVD method and the step of conducting annealing at an annealing temperature set equal to or higher than the deposition temperature of the film is further comprised.

11. A method of manufacturing a semiconductor integrated circuit device according to claim 11, wherein said annealing is carried out either after the formation of said silicon film but before the formation of said gate electrode or after the formation of said gate electrode.
